(19) United States
(12) Patent Application Publication
(10) Pub. No.: US 2013/0208743 A1
(43) Pub. Date: Aug. 15, 2013

(54) BROADBAND QUANTUM CASCADE LASER SOURCE

(71) Applicants: Federico Capasso, Cambridge, MA (US); Christian Pfluegl, Cambridge, MA (US); Laurent Diehl, Cambridge, MA (US); Romain Blanchard, Cambridge, MA (US)

(72) Inventors: Federico Capasso, Cambridge, MA (US); Christian Pfluegl, Cambridge, MA (US); Laurent Diehl, Cambridge, MA (US); Romain Blanchard, Cambridge, MA (US)

(73) Assignee: President and Fellows of Harvard College, Cambridge, MA (US)

(21) Appl. No.: 13/816,385

(22) PCT Filed: Aug. 2, 2011
(86) PCT No.: PCT/US11/46265

§ 371 Date: Apr. 24, 2013

Related U.S. Application Data
(60) Provisional application No. 61/372,603, filed on Aug. 11, 2010.
(60) Provisional application No. 61/380,430, filed on Sep. 7, 2010.

(51) Int. Cl. H01S 5/125

(52) U.S. Cl. CPC H01S 5/125
USPC 372/29.015

(57) ABSTRACT

A broadband quantum cascade laser (QCL) source includes one or more QCLs having an active region designed based on a diagonal laser transition. The QCL source may include multiple QCLs formed in an array or the QCL source may comprise a single QCL device. Although each QCL provides an emission spectrum comprising a small range of wavelengths at a given applied voltage, changes in the applied operating voltage result in changes in the emission spectrum of the QCL due to the Stark shift. When the QCL source comprises a plurality of QCLs formed in an array, at least some of the elements in the array may receive different applied operating voltages such that the combined output spectrum of the array is broader than that achievable by a single QCL. When the QCL source comprises a single QCL device, an applied operating voltage may be swept through a range of applied voltages such that that combined output spectrum over one sweep cycle is broader than the output spectrum of the QCL device when a static operating voltage is applied. Alternatively, the single QCL device may comprise multiple independent gain sections, wherein each of the independent gain sections is configured to operate at a different voltages to provide a broadband output spectrum.

### BACKGROUND

Quantum Cascade Lasers (QCLs) are unipolar semiconductor lasers that utilize optical transitions between confined electronic sub-bands (e.g., conduction or valence bands) of semiconductor heterostructures. As a result, the emitted photon energy is determined by the thicknesses of the wells and barriers in a heterostructure and can be tailored by bandgap engineering.

In a QCL, the gain medium comprises a repetition of stages connected in series. In general, each stage includes two groups of quantum wells, i.e., a first group called the active region in which the laser transition takes place, and a second group called the injector region, which allows for the transport of electrons from one active region to the next. For applications that do not require broadband coverage, all of the stages in the QCL may be based on an identical active region design to maximize the gain in a narrow wavelength of interest. In contrast, QCLs with a broad gain curve, also called QCLs based on heterogeneous cascades, include a number of stages based on different active region designs with each stage having the laser transition centered at a different wavelength. In such heterogeneous stage designs, the number of stages emitting at each specific wavelength, as well as the doping level in each injector region, may be adjusted to obtain an essentially flat modal net gain across a wavelength region of interest.

QCLs may be fabricated to emit multiple beams of narrow-bandwidth radiation simultaneously at relatively widely separated wavelengths. This may be achieved, for example, using a heterogeneous structure including a stack of two or more active regions designed for emission at specific wavelengths. Alternatively, QCLs may be fabricated as a broadband source that emits over a wide spectrum. This may be achieved, for example, using a “bound-to-continuum” design with a structure that includes a stack of two or more active regions, each designed for emission at different wavelengths, or using a heterogeneous structure including many active regions designed for emission at slightly different wavelengths. Thus, a single QCL chip can emit light in wide ranges of mid-IR frequencies.

Although some QCLs have been designed as broadband sources to emit over a large spectral range, lasing typically only occurs over certain parts of this spectral range. Due to the homogeneous broadening of the lasing transition, gain competition in single broadband or multi-wavelength devices usually prevents continuous lasing over most parts of the gain region. Conventional QCLs are typically operated by applying a static operating voltage. In some cases, the gain spectrum of QCLs may be altered by changing the applied operating voltage if the active region design is based on a diagonal laser transition as shown in FIG. 1. An exemplary QCL where this effect is significant was developed by Bismuto et al. In this device, the transition energy and thus the emission spectrum changes with the applied electric field due to the Stark shift.

### SUMMARY

Applicants have recognized and appreciated that although some QCL designs can provide gain over a large spectral range, the emission spectrum of the QCL at a given voltage applied to the QCL is limited. In view of the foregoing, various embodiments of the present invention are directed to generating a broadband emission spectrum using one or more QCLs in which respective output beams occupy a greater portion of the broadband spectrum.

In one exemplary embodiment, the outputs from multiple QCLs operating at different applied voltages are combined to provide a broadband QCL source. Other embodiments are directed to a single QCL device configured to generate a broadband emission spectrum by sweeping a voltage applied to the single QCL device.

In sum, some embodiments of the invention are directed to a broadband quantum cascade laser (QCL) source. The broadband QCL source comprises an array of QCLs, wherein at least two of the QCLs in the array are configured to operate at different applied voltages.

Another embodiment is directed to a method for providing broadband radiation emission. The method comprises defining on a common wafer an array of quantum cascade lasers, wherein at least some of the quantum cascade lasers in the array are configured to be operated at different applied voltages resulting in emission at different spectral regions.

Another embodiment is directed to a method for providing a broadband emission spectrum using a single quantum cascade laser device, wherein an emission spectrum output from the single quantum cascade laser device changes in response to changes in an applied voltage signal. The method comprises sweeping the applied voltage signal to produce the broadband emission spectrum.

Reliable operation of broadband QCL sources in the mid-infrared and terahertz spectral regions (3-24 μm wavelength range) according to the embodiments of the present invention cover the so-called molecular fingerprint region of the optical spectrum in which molecules have unique and strong rotational-vibrational absorption features that allow for their identification. QCL operation in this wavelength range may be useful for chemical and biological sensing, remote sensing, high-resolution spectroscopy, infrared detection, and many other applications.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference or otherwise referenced herein should be accorded a meaning most consistent with the particular concepts disclosed herein.

### BRIEF DESCRIPTION OF THE DRAWINGS

The drawings are not necessarily to scale, emphasis instead generally being placed upon illustrating the principles of the invention.

FIG. 1 schematically shows a conventional QCL with an active region design based on a diagonal laser transition;

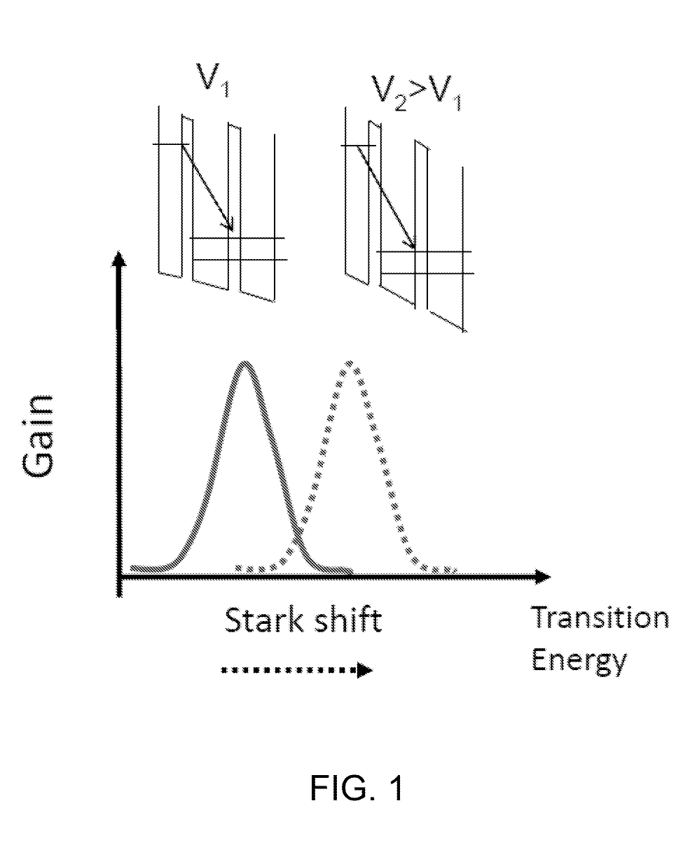

FIGS. 2A and 2B illustrate, respectively, an exemplary QCL array and an applied voltage diagram for the exemplary QCL in FIG. 2A in accordance with some embodiments of the invention;

FIG. 3 shows an exemplary QCL element in accordance with some embodiments of the invention;

FIGS. 4A and 4B show, respectively, an exemplary QCL structure having multiple gain mediums and a corresponding output gain with an applied voltage diagram in accordance with some embodiments of the invention;

FIGS. 5A and 5B illustrate, respectively, a step pattern and a continuous sweep pattern for applying a voltage to a QCL source in accordance with some embodiments of the invention; and

FIGS. 6A and 6B illustrate, respectively, an exemplary broadband QCL device having multiple independent controllable gain sections and a corresponding output gain with applied voltage diagram in accordance with some embodiments of the invention.

### DETAILED DESCRIPTION

Following below are more detailed descriptions of various concepts related to, and embodiments of, inventive methods and apparatus according to the present disclosure relating to broadband emission from quantum cascade lasers. It should be appreciated that various concepts introduced above and discussed in greater detail below may be implemented in any of numerous ways, as the disclosed concepts are not limited to any particular manner of implementation. Examples of specific implementations and applications are provided primarily for illustrative purposes.

In one embodiment, a broadband infrared laser source that simultaneously emits multiple radiation beams over a large spectral range may be achieved using an array of closely-spaced QCLs, with at least some of the QCLs in the array having an active region design based on a diagonal laser transition. A laser transition may be considered to be diagonal when the center of mass of the upper laser state is different than the center of mass of the lower laser state. In such diagonal designs the emission wavelength of the QCL depends on the operating voltage applied to the QCL. It should be appreciated that QCLs having an active region design with any degree of diagonality may be used and embodiments of the invention are not limited in this respect. Furthermore, each of the QCLs in the array may comprise an identical structure or they may have different structures depending on a particular application for which the QCL array was designed.

In some embodiments, the array of QCLs may be fabricated on a common QCL wafer and at least some of the QCLs in the array may be operated at different applied voltages such that the combined output spectrum from the array of QCLs covers a wide spectral range. In some embodiments, the QCLs in the array may be configured to be operated independently from each other to enable the properties of the combined output spectrum to be changed.

To increase the output power at a specific wavelength range, the same (or similar) operating voltage may be applied to multiple QCLs in the array. Since both the output spectrum and the output power of a QCL changes with applied voltage, in some embodiments, different QCLs in the array may be configured to have different sizes (e.g., width of the waveguide) to compensate for differences in output power between the QCLs. Differences in output power may be addressed in other ways as well, including, but not limited to, adding one or more power amplifier stages to the QCLs in the array, with the gain of each power amplifier stage being configured to compensate for differences in output power of associated QCLs. For example, an array of power amplifier stages may be monolithically integrated with the array of QCLs and the gain of each amplifier stage may be configured such that the output power of each of the associated QCLs in the array is approximately the same.

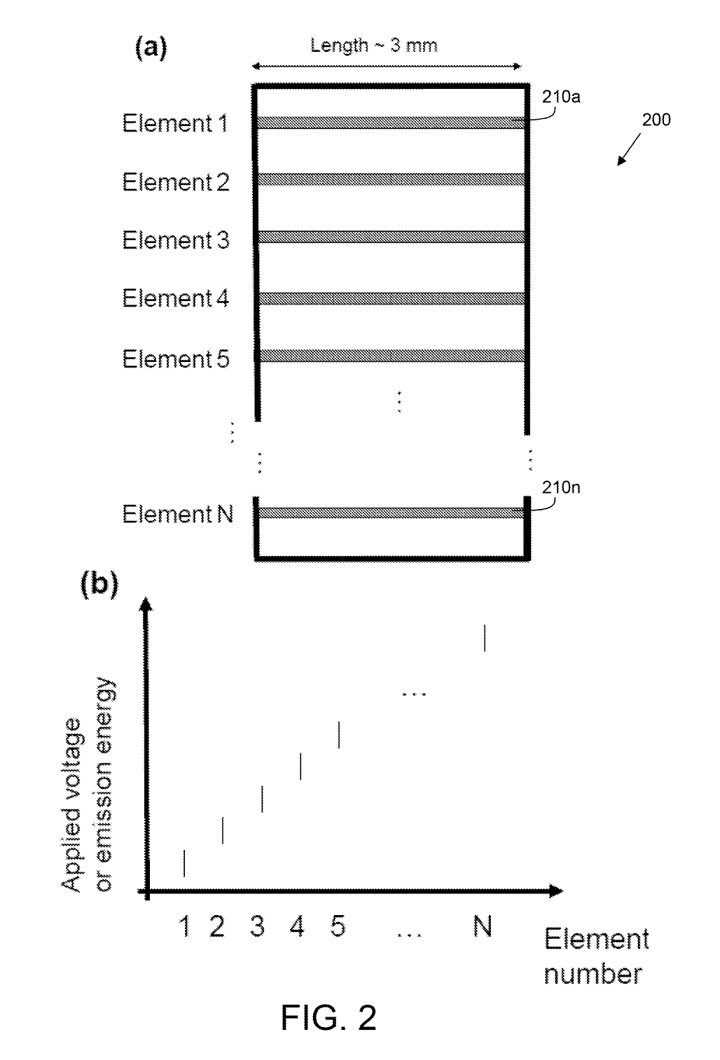

An exemplary implementation of a QCL array in accordance with some embodiments of the invention is shown in FIG. 2A. The QCL array 200 comprises a plurality of laser elements 210a-210n (e.g., Fabry-Perot QCLs) fabricated next to each other. As described above, in some embodiments, laser elements 210a-210n may have an identical structure, although the particular structure of laser elements used in QCL array 200 does not limit embodiments of the invention in any way. As described above, at least some of the QCLs in array 200 may be operated at different applied voltages as shown in FIG. 2B. By operating at least some of the QCLs in QCL array 200 at different voltages, the QCL array 200 may be configured to emit over a desired wavelength region of interest. By adjusting the operating voltages applied to different elements of the QCL array 200, the output spectrum of the QCL array 200 may be altered to cover a different spectral range. QCL array 200 may include any suitable number of elements 210a-210n and embodiments of the invention are not limited in this respect.

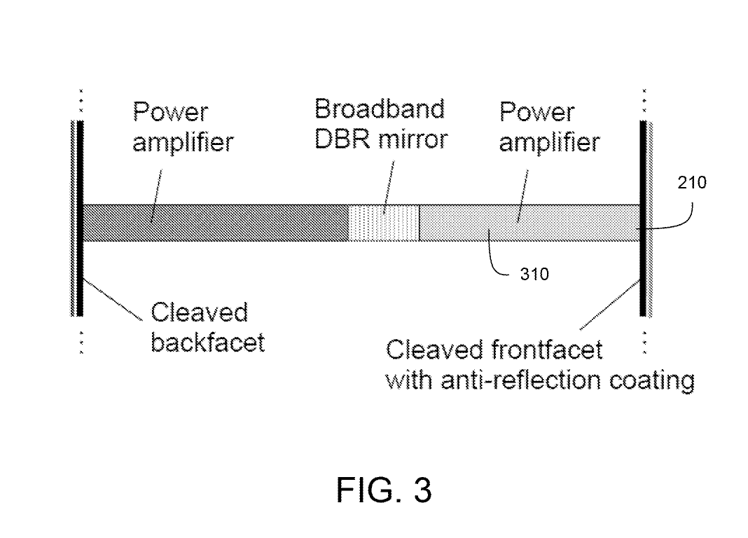

In some embodiments, the output (emission) spectrum of individual QCLs in QCL array 200 may be fine-tuned by configuring one or more QCLs in the array as a distributed feedback (DFB) QCL and/or by employing Bragg reflectors (BRs) in the QCL design, as illustrated in FIG. 3. An external grating in conjunction with Fabry-Perot lasers or wavelength selective facet coatings may additionally or alternatively be used to fine-tune the spectrum of individual elements in QCL array 200. The DFB/DBR or external gratings may help to optimize the overall combined emission spectrum of QCL array 200 in addition to fine-tuning the output spectrum of individual elements in the array.

As described above, variations in the operating voltage applied to individual elements of QCL array 200 result in differences in output power for the individual elements in the array. Lower output power at certain spectral regions may also be observed, for example, when an individual QCL is operated slightly above threshold current. In some embodiments, to compensate for individual elements with lower output power, power amplifiers 310 may be monolithically integrated in front of at least some of the individual lasers 210 to increase the output power of single elements and to adjust the overall spectrum. It should be appreciated that the output power of individual elements may be adjusted in any suitable way and using an array of integrated power amplifiers to fine-tune the output power as shown in FIG. 3 is described for exemplary purposes only.

The outputs of individual elements 210 in the QCL array 200 may be combined in any suitable way. For example, the outputs may be combined with or without external optics and embodiments of the invention are not limited in the particular manner in which the outputs of individual QCLs are combined.

In some embodiments, the individual elements 210 of QCL array 200 may be operated sequentially rather than being operated simultaneously and embodiments of the invention are not limited in the order or manner in which the individual elements 210 are operated.

The range of spectral coverage provided by the combined output of QCLs in QCL array 200 may be tailored to a particular implementation and embodiments of the invention are not limited in this respect. For example, in some embodiments, the output of QCL array 200 may cover a broad spectral range, whereas in other embodiments the individual elements 210 in QCL array 200 may be designed to cover only certain spectral regions of interest for a given application.

Although particular designs for individual elements 210 in QCL array 200 have been described above, it should be appreciated that any QCL design which has an emission spectrum that depends on an applied operating voltage may alternatively be used and embodiments of the invention are not limited in this respect. For example, QCLs with an active region design with at least two upper laser states and/or an active region design with at least two lower laser states may be used in QCL array 200.

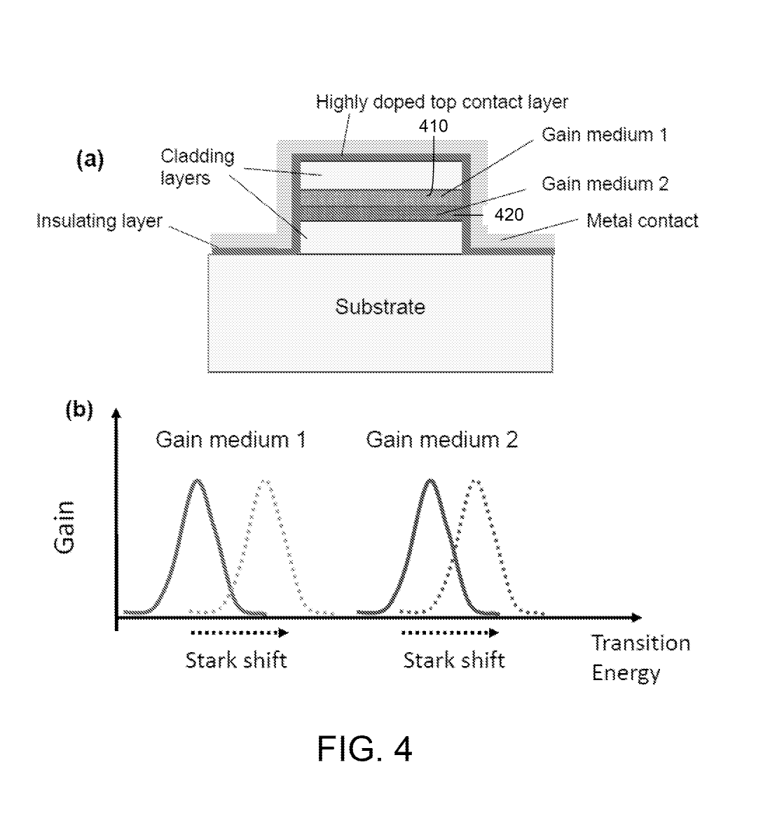

In some embodiments, individual laser elements 210 may comprise at least one stack of different gain media as shown in FIG. 4. The QCL illustrated in FIG. 4 comprises a first gain medium 410 configured to emit in a first spectral range and a second gain medium 420 configured to emit in a second spectral range. By including multiple gain media, the spectral coverage of individual QCLs may be increased. It should be appreciated however, that a QCL having any number of gain media may also be used, and the QCL shown in FIG. 4, which employs two gain media is merely provided as an example.

Some embodiments are directed to a broadband QCL source that uses a single QCL device based on a diagonal transition rather than using an array of QCL devices, as described above. Applicants have recognized and appreciated that a broadband source may be achieved by tuning the single QCL device over a broad spectral range by sweeping or changing the applied operating voltage. Since the emission spectrum changes with the applied voltage, the integrated spectral output over one sweeping cycle of the single QCL device may cover a large spectral range. Such a single QCL may be used for a range of applications including, but not limited to, as a spectrally broad light source if the sweep frequency is larger than the response time of the detector used for the experiment and as a spectrally broad light source for Fourier transform infrared (FTIR) spectrometers if the scanning frequency of the FTIR is smaller than the sweep frequency. For example, a typical scanning frequency for an FTIR is less than 10 kHz. If the sweep frequency is greater than 10 kHz (e.g., 1 MHz), then the output of the QCL device may appear to the FTIR as a broadband light source.

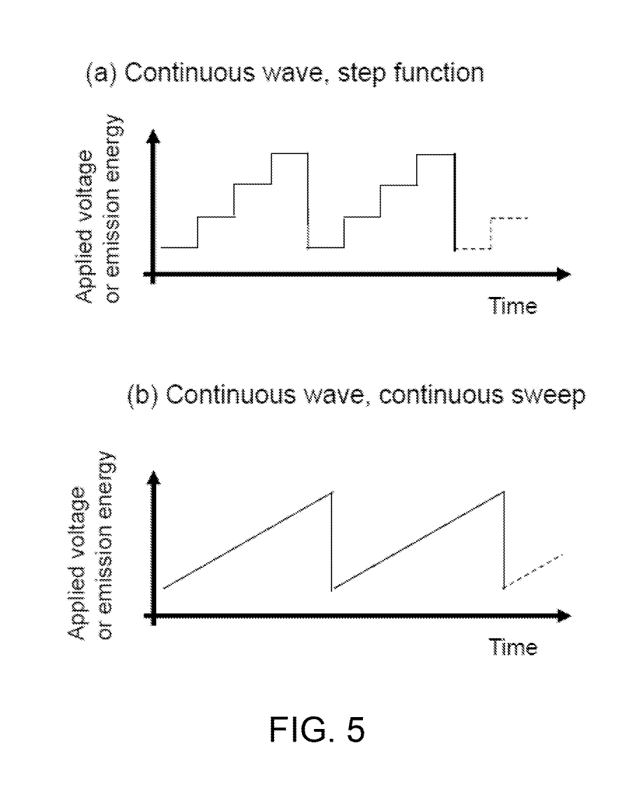

The operating voltage applied to the single QCL device may be swept or changed in any suitable way and embodiments of the invention are not limited in this respect. For example, instead of continuously sweeping the voltage, the voltage may be changed incrementally in steps as shown in FIG. 5.

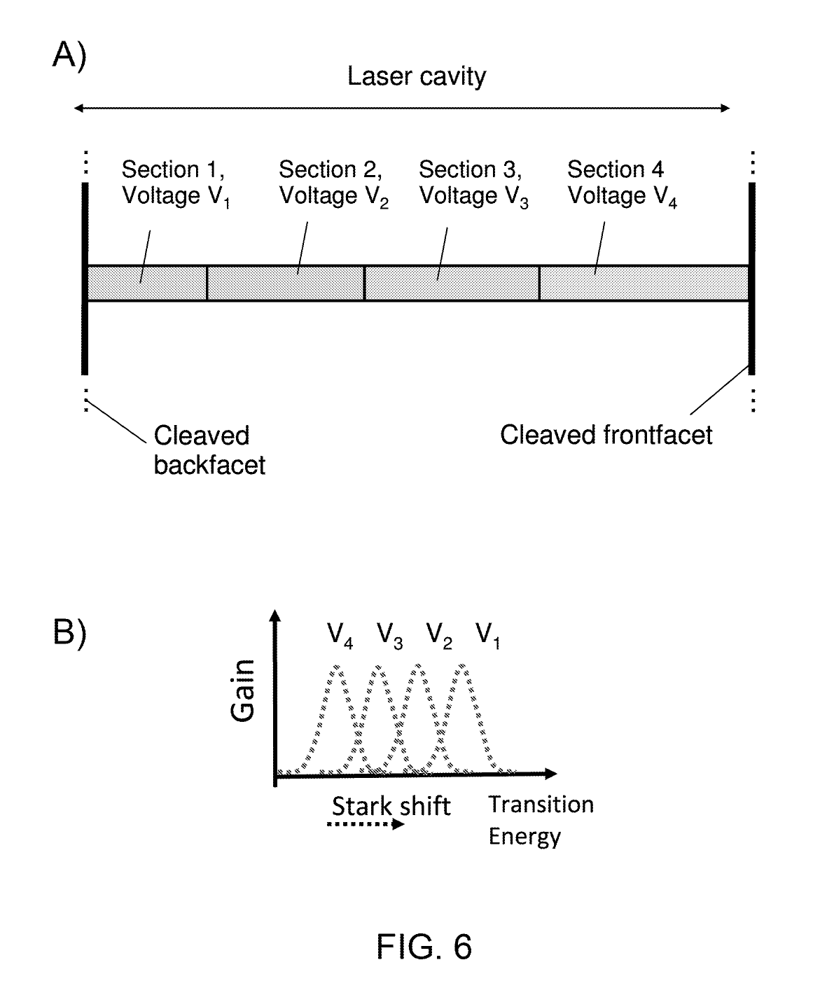

In some embodiments, a single QCL device may comprise a plurality of independent gain sections and electrical contacts as illustrated in FIG. 6A. The exemplary QCL shown in FIG. 6A includes four independent gain sections, wherein a different voltage is applied to each of the four independent gain sections. By biasing each of the independent gain sections at a different voltage, the QCL may provide continuous lasing over a broad gain spectrum or lasing over one or more wavelengths of interest. For example, FIG. 6B schematically illustrates a output spectrum of the exemplary QCL shown in FIG. 6A, where V₁>V₂>V₃>V₄. As should be apparent from FIG. 6B, the overlapping gain spectra output from the plurality of independent gain sections of the QCL in FIG. 6A results in lasing over a broad spectrum. Although the QCL in FIG. 6A is shown with four independent gain sections, it should be appreciated that any suitable number of independent gain sections may be used and embodiments of the invention are not limited in this respect.

An amount of gain in a QCL is proportional to the current density flowing through the QCL, which, as described above, is a function of the applied voltage. As a consequence, independent gain sections operated at a low voltage experience less optical gain than sections operated at higher voltages due to the reduced current flow at lower operating voltages. One way to compensate for these differences is to vary the length of the independent gain sections based on the voltage applied to each section as shown in FIG. 6A. By making the gain sections operated at lower voltages longer (e.g., section 4 in FIG. 6A) than the gain sections operated at higher voltages (e.g., section 1 in FIG. 6A), the gain in each of the sections experienced in each of the independent gain sections may be more homogenous throughout the QCL.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A broadband quantum cascade laser (QCL) source, comprising:
an array of QCLs, wherein at least two of the QCLs in the array are configured to operate at different applied voltages.

2. The broadband QCL source of claim 1, wherein the at least two of the QCLs are configured to emit within different spectral ranges in response to the different applied voltages.

3. The broadband QCL source of claim 1, wherein at least two of the QCLs in the QCL array are configured to be operated simultaneously.

4. The broadband QCL source of claim 1, wherein at least two of the QCLs in the QCL array are configured to be operated sequentially.

5. The broadband QCL source of claim 1, wherein at least two of the QCLs in the QCL array are configured to emit within the same spectral range.

6. The broadband QCL source of claim 1, wherein at least two QCLs in the QCL array have different sizes to compensate for output power differences between the at least two QCLs in the QCL array.

7. The broadband QCL source of claim 1, wherein the outputs of the QCLs in the QCL array are monolithically combined to produce a broadband emission spectrum.

8. The broadband QCL source of claim 1, wherein the outputs of the QCLs in the QCL array are combined using at least one external optic.

9. The broadband QCL source of claim 1, wherein an active region of at least one QCL in the QCL array is designed based on a diagonal laser transition.

10. The broadband QCL source of claim 1, wherein at least one QCL in the QCL array is a Fabry-Perot laser.

11. The broadband QCL source of claim 1, wherein at least one QCL in the QCL array is a distributed feedback (DFB) laser.

12. The broadband QCL source of claim 1, further comprising:
at least one Bragg reflector associated with at least one QCL in the QCL array, wherein the at least one Bragg reflector is configured to tune the spectral emission of the at least one QCL.

13. The broadband QCL source of claim 1, wherein an active region of at least one QCL in the QCI, array comprises at least two upper laser states.

14. The broadband QCL source of claim 1, wherein an active region of at least one QCL in the QCL array comprises at least two lower laser states.

15. The broadband QCL source of claim 1, wherein an active region of at least one QCL in the QCL array comprises a plurality of gain regions, wherein each of the plurality of gain regions is configured to emit radiation at a particular wavelength.

16. The broadband QCL source of claim 1, further comprising:
at least one power amplifier associated with at least one QCL in the QCL array, wherein the at least one power amplifier is configured to adjust an output power of the at least one QCL.

17. A broadband quantum cascade laser (QCL) source, comprising:
a single QCL device configured to output a broadband emission spectrum in response to a sweeping applied voltage signal.

18-20. (canceled)

21. A method for providing broadband radiation emission, the method comprising:
defining on a common wafer, an array of quantum cascade lasers, wherein at least some of the quantum cascade lasers in the array are configured to be operated at different applied voltages resulting in emission at different spectral regions.

22. The method of claim 21, further comprising:
associating, with at least one quantum cascade laser in the array of quantum cascade lasers, at least one power amplifier configured to increase an output power of the at least one quantum cascade laser.

23. The method of claim 21, further comprising:
associating, with, at least one quantum cascade laser in the array of quantum cascade lasers, at least one Bragg reflector, wherein the at least one Bragg reflector is configured to tune an output of the at least one quantum cascade laser.

24-28. (canceled)
